(19) United States
(12) Patent Application Publication
(10) Pub. No.: US 2026/0245844 A1
(43) Pub. Date: Aug. 20, 2026

(54) SERVER, SEMICONDUCTOR DEVICE MANUFACTURING SYSTEM AND MANUFACTURING METHOD

(71) Applicant: HITACHI HIGH-TECH CORPORATION, Minato-ku, Tokyo (JP)

(72) Inventors: Tooru ARAMAKI, Tokyo (JP); Go SAITO, Tokyo (JP); Makoto SATAKE, Tokyo (JP); Wataru NAGATOMO, Tokyo (JP); Hitoshi NAMAI, Tokyo (JP); Takefumi KAKINUMA, Tokyo (JP)

(21) Appl. No.: 18/840,201

(22) PCT Filed: Aug. 24, 2023
(86) PCT No.: PCT/JP2023/030479

§ 371 Date: Aug. 21, 2024

(51) Int. Cl. H01J 37/32; G05B 19/418; H10P 72/00; H10P 74/00

(52) U.S. Cl. CPC H01J 37/32935; G05B 19/4183; H10P 72/0421; H10P 74/23; G05B 2219/45031; H01J 2237/334

(57) ABSTRACT

A system and method for detecting a shape defect that cannot be obtained by only planar dimension data, including a server configured to control an etching parameter to obtain a desired processing result of a semiconductor manufacturing apparatus based on correlation data between the etching parameter of the semiconductor manufacturing apparatus and a change amount between a target value and a feature of an etched shape formed on a sample, and the feature is a value obtained based on secondary electron data from a surface of the sample or interference light data from the surface of the sample. The feature may be a value obtained from a dimension of the etched shape of the sample based on the secondary electron data or the interference light data. The change amount of the feature may be a value of a spatial or temporal change.

### TECHNICAL FIELD

The present invention relates to a server, and a semiconductor device manufacturing system and manufacturing method.

### BACKGROUND ART

A plasma etching system is currently a part of a semiconductor manufacturing tool for manufacturing a semiconductor device approaching miniaturization of an atomic level. One requirement of a device manufacturing apparatus is improvement in uniformity. In order to manufacture a semiconductor device approaching an atomic level, it has been found that it is insufficient to simply measure a dimension in a lateral direction of a semiconductor device by observing the semiconductor device from an upper surface of a wafer and then perform uniformization based on measured data. For example, there is a CD-SEM in a measuring device, but only a dimension of a surface of a pattern can be obtained based on a geometric planar dimension data of a top view obtained from the CD-SEM, and thus a bowing shape or a notch shape of a portion slightly deeper than the surface of the pattern cannot be measured. Accordingly, even with the same critical dimension (CD) value, it is not possible to detect a three-dimensional geometric defect of a pattern. When a defect cannot be detected in this manner, it is apparent that a defect will occur in an ion implantation process or a CVD process after etching. Since a defective shape relates not only to a temperature of an electrostatic chuck during etching but also to a plasma density, complicated etching parameter control is required.

In the related art, as disclosed in PTL 1, based on a CD value which is geometric dimension data of a top view, a temperature value of an electrostatic chuck is fed back based on a variation in the CD value in a wafer surface to achieve a uniform CD value in the wafer surface and improve a yield in the wafer surface.

### CITATION LIST

### Patent Literature

PTL 1: JP5925943B

### SUMMARY OF INVENTION

### Technical Problem

However, since the technique disclosed in the related art is a technique for making the CD value uniform, it is not possible to cope with a situation where a defect such as a bowing shape or a notch shape occurs in a depth direction even though the CD value is the same. Since the technique is a technique of feeding back a temperature of an electrostatic chuck, it is not possible to cope with a defect of a pattern shape caused by a plasma density.

An object of the invention is to provide a technique for detecting a shape defect that cannot be obtained by planar dimension data obtained from a top view and accurately controlling an etching parameter.

### Solution to Problem

In order to solve the above problems, one representative invention is a server, in which an etching parameter is controlled to obtain a desired processing result of a semiconductor manufacturing apparatus based on correlation data between the etching parameter of the semiconductor manufacturing apparatus and a change amount between a target value and a feature of an etched shape formed on a sample, and the feature is a value obtained based on secondary electron data from a surface of the sample or interference light data from the surface of the sample.

### Advantageous Effects of Invention

According to the invention, it is possible to detect a shape defect that cannot be obtained by planar dimension data obtained from a top view and accurately control an etching parameter. A user optimize an etching processing recipe that is nondestructive and does not cause a device defect without observing a cross section of a wafer when or before a device defect occurs.

Problems, configurations, and effects other than those described above will become apparent in the following description in embodiments.

### BRIEF DESCRIPTION OF DRAWINGS

FIG. 1 is a schematic diagram showing a semiconductor device manufacturing system according to a first embodiment.

FIG. 2A is a correlation diagram between a pattern shape and a secondary electron profile when an acceleration voltage is high.

FIG. 2B is a correlation diagram between a pattern shape and a secondary electron profile when the acceleration voltage is low.

FIG. 3 is a correlation diagram between a pattern shape and a secondary electron profile under predetermined etching parameters.

FIG. 4 is a flowchart showing an example of a method for performing etching parameter control according to the first embodiment.

FIG. 5 is a flowchart showing an example of a method for performing etching parameter control according to a second embodiment.

FIG. 6 is a correlation diagram between a pattern shape and a secondary electron profile for a predetermined number of etched wafers.

FIG. 7 is a flowchart showing an example of a method for extracting a combination of features having a high correlation coefficient with an etching parameter.

FIG. 8 is a schematic diagram showing a feature map according to a fourth embodiment.

FIG. 9 is a flowchart showing an example of a method for performing etching parameter control according to the fourth embodiment.

FIG. 10 is a correlation diagram between a feature and an etching parameter.

### DESCRIPTION OF EMBODIMENTS

Hereinafter, embodiments of the invention will be described with reference to the drawings. The invention is not limited to the embodiments. In the description of the drawings, the same portions are denoted by the same reference numerals.

According to an embodiment of the invention, a server calculates, based on a feature obtained based on a secondary electron profile obtained from a top view of a wafer using a CD-SEM, a temporal change amount of the feature or a spatial change amount of the feature, or calculates a geometric dimensional difference (change amount) between a feature of an etched shape and a feature of a target shape and an integrated value in an etching depth direction of the geometric dimensional difference (change amount), and performs etching parameter control in a semiconductor manufacturing apparatus based on correlation data. Hereinafter, embodiments will be described with reference to the drawings.

### First Embodiment

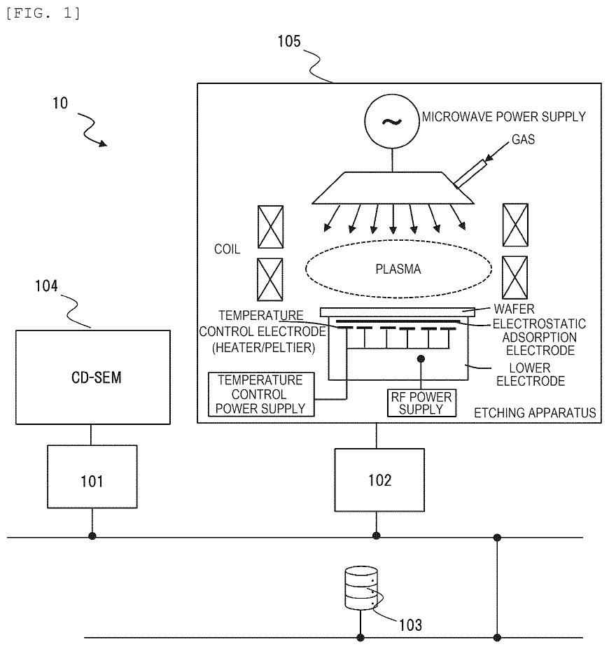

A first embodiment of the invention will be described with reference to FIG. 1. FIG. 1 is a schematic diagram showing a semiconductor device manufacturing system according to the first embodiment. A semiconductor device manufacturing system 10 includes an apparatus group including a semiconductor manufacturing apparatus (an etching apparatus) 105, a CD-SEM PC 101, a semiconductor manufacturing apparatus, and a semiconductor inspection apparatus 104 (for example, a CD-SEM), and a server 103. An object of the drawing is to describe performance improvement of an important semiconductor device manufacturing system in semiconductor manufacturing.

A processing recipe for performing etching processing is input to the semiconductor manufacturing apparatus PC 102 or transferred from the server 103 to the PC 102, and the processing recipe is executed. After the execution, the etching apparatus 105 transmits an instruction value corresponding to contents of the processing recipe to each device in the etching apparatus to perform etching processing. Devices and components described in FIG. 1 are main devices and components, and include a wafer temperature control power supply, a temperature control electrode (heater/Peltier), an RF power supply for applying a radio frequency, a microwave power supply for generating plasma, a gas for generating plasma, a magnetic field generation coil for adjusting a plasma density, an electrostatic adsorption electrode (an electrostatic chuck), and a lower electrode. A wafer which is a sample is placed on the electrostatic adsorption electrode and is etched by plasma processing. The executed processing recipe can be stored in the server 103 via the semiconductor manufacturing apparatus PC 102. Hereinafter, unless specified otherwise, in-plane refers to a surface of the sample (the wafer). The wafer will be described as a wafer having a circular shape having a radial direction and a circumferential direction.

The etched wafer is conveyed to the semiconductor inspection apparatus 104 (for example, a CD-SEM). In FIG. 1, a CD-SEM recipe is input to the CD-SEM PC 101 and predetermined measurement is performed. Here, an electron beam is used in the measurement, and a feature is calculated based on a secondary electron amount (secondary electron data) after irradiating the etched wafer with the electron beam. Here, a feature obtained based on an intensity profile of the secondary electron amount (a secondary electron profile) is used as a representative feature. There are various other features such as a feature using illuminance data and a feature obtained by differentiating the intensity profile (a feature obtained based on the secondary electron profile derived from an etched shape of the sample may be referred to as a profile feature). A measurement result can be stored in the server 103 via the PC 101.

By using the stored measurement data, a wafer yield is visualized based on a feature distribution in a wafer surface, and when a calculated yield value cannot be satisfied, a processing recipe for performing the etching processing again is corrected. Even when CD values are the same, in a case where features are different, it is considered that there is a defect in a pattern shape of a device. This will be described in more detail below.

### (Secondary Electron Profile)

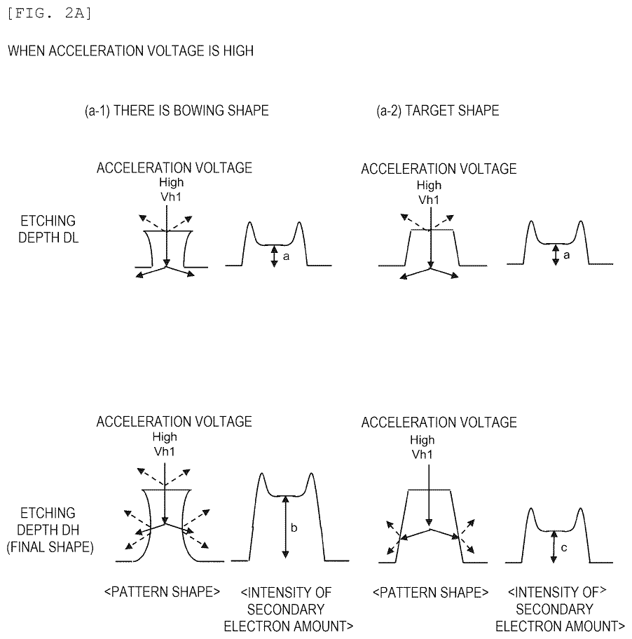

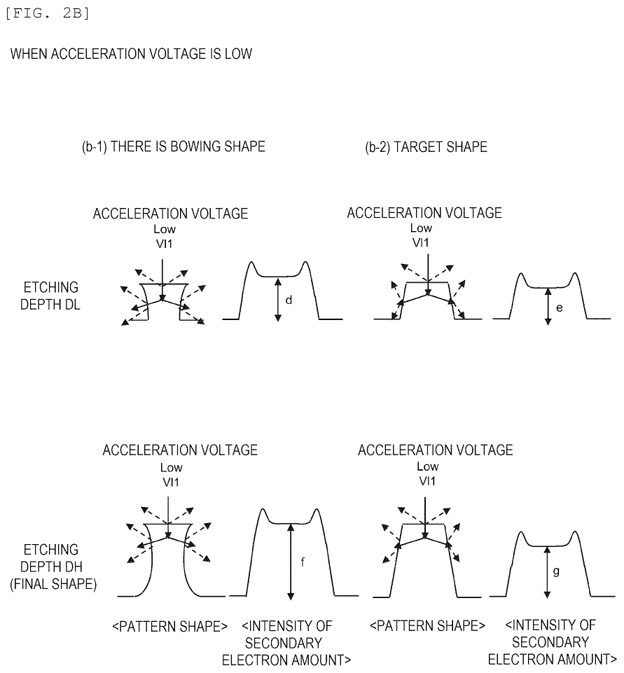

FIG. 2A is a correlation diagram between a pattern shape and a secondary electron profile when an acceleration voltage is high. FIG. 2B is a correlation diagram between a pattern shape and a secondary electron profile when the acceleration voltage is low. Hereinafter, FIG. 2A and FIG. 2B may be collectively referred to as FIG. 2 for convenience. In FIG. 2, a schematic diagram of a pattern shape of a device is shown on the left, and a schematic diagram of an intensity profile of a secondary electron amount (a secondary electron profile) is shown on the right. All Top CD values of pattern shapes in FIG. 2 are the same. Since a difference in the secondary electron amount occurs depending on high or low of the acceleration voltage, there is an optimum acceleration voltage at which it is easy to extract a defective shape. Here, a bowing shape will be described as an example of the defective shape, and a concept about how the secondary electron profile changes when the acceleration voltage is high and when the acceleration voltage is low, and which one is optimum will be described. A pattern shape of a device may be referred to as an etched shape when the device is formed by etching.

FIG. 2A shows a case where the acceleration voltage is high (an acceleration voltage: Vh1). (a-1) shows a case where there is a bowing shape (a defective shape) and (a-2) shows a case of a target shape. Since a penetration depth of primary electrons of the acceleration voltage is deep, at an etching initial depth DL, an amount of secondary electrons that seep out from side walls of a pattern is small, and accordingly, a secondary electron amount is small. Therefore, both a feature of a pattern shape (an intensity of a secondary electron amount at a center of a top surface of a pattern) in the case of a bowing shape in which a lateral width is small and a feature of a target shape (hereinafter, the feature of the target shape is simply referred to as a target value) when a lateral width has a normal value are a and there is no difference (change amount), and it is difficult to detect the bowing shape.

As the etching proceeds, at an etching depth DH of a final shape, as shown in (a-1), an amount of secondary electrons that seep out from side walls of a pattern increases, so that a value of a feature (an intensity of a secondary electron amount at the center of the top surface of the pattern) increases to b. Therefore, since the value is larger than a target value c, a bowing shape can be easily detected. That is, in the case of b−a>c−a (that is, b>c), it can be determined that there is a bowing shape.

On the other hand, as shown in FIG. 2B, when the acceleration voltage is low (an acceleration voltage: V11), since a penetration depth of primary electrons is shallow, at an etching initial depth DL, even when a bowing shape is small as shown in (b-1), an amount of secondary electrons that seep out from side walls of a pattern is large, and accordingly, a value of a feature (an intensity of a secondary electron amount at a center of a top surface of a pattern) is d and is large. Therefore, d-e which is a difference (change amount) between d and a target value e is large, and a bowing shape can be easily detected even at an etching initial stage. Naturally, as the etching processing proceeds, at an etching depth DH of a final shape, similarly, f-g which is a difference (change amount) between a feature and a target value is large, and at this time, a bowing shape can also be easily detected.

As described above, since the ease of detection of a pattern shape defect is changed by adjusting the acceleration voltage applied to primary electrons at the time of irradiating with an electron beam, it is important to adjust the acceleration voltage to be optimum.

As described above, since the profile feature also includes information on an etching depth direction of an etched shape, by calculating a difference of a profile feature in a wafer surface, it is possible to calculate a defect such as a bowing shape in the etching depth direction which cannot be obtained by only planar dimension data obtained from a top view. A more detailed change in a feature may be calculated by calculating a change in the feature by tilting a wafer using a tilt function of a CD-SEM.

### (Feature and Etching Parameter)

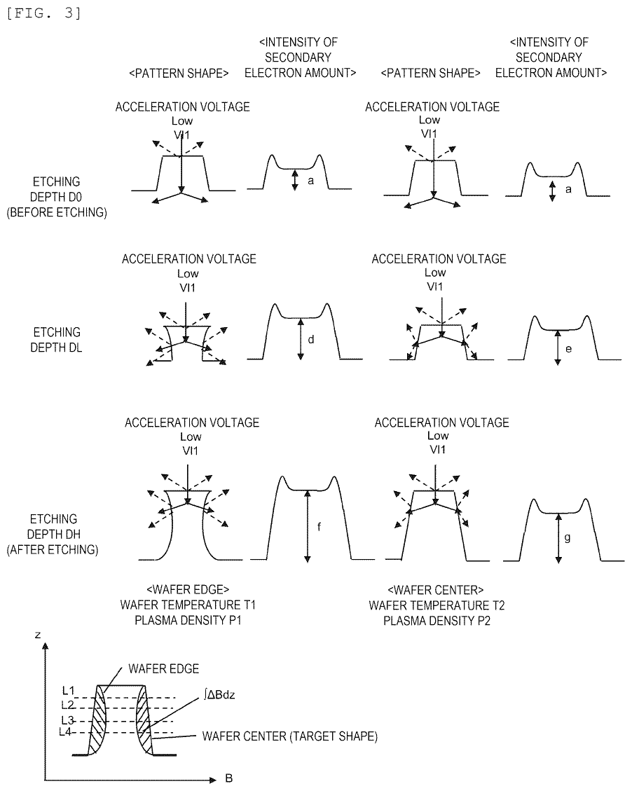

Next, a correlation between a feature and an etching parameter will be described. FIG. 3 is a correlation diagram between a pattern shape and a secondary electron profile under predetermined etching parameters. For example, a pattern shape and a feature at a wafer edge, a pattern shape and a feature at a wafer center, and a temperature environment and a plasma density environment serving as etching parameters at respective places are shown. Here, for example, a device at the wafer center has a pattern target shape, a temperature at the wafer center is T2, and a plasma density at the wafer center is P2. A temperature at the wafer edge is T1 and a plasma density at the wafer edge is P1 at a place where a device at the wafer edge has a bowing shape and a defect occurs. FIG. 3 shows a graph schematically showing pattern shapes at the wafer edge and at the wafer center with a vertical axis of z and a horizontal axis of B. L1 to L4 are film type switching lines. A shaded area indicates a shape difference between the wafer edge and the wafer center. An area of a shape difference portion (an area difference) is ∫ΔBdz. Here, there are two methods for calculating the ∫ΔBdz to optimize the etching parameter or optimize the etching parameter without calculating the ∫ΔBdz, and the two methods are described as below.

### Method 1

Method 1 is a method for performing etching parameter control without specifying ∫ΔBdz.

First, ∫ΔBdz can be expressed as Formula 1 using a function Q.

$$\int Δ Bdz = Q ( ( f - a ) - ( g - a ) ) \qquad Formula 1$$

Next, when an electrostatic chuck temperature difference ΔT=T1-T2 and a plasma density difference ΔP=P1-P2, ∫ΔBdz can be expressed as Formula 2 using a function R.

$$\int Δ Bdz = R ( Δ T , Δ P ) \qquad Formula 2$$

From Formulas 1 and 2,

$$Q ( f - g ) = R ( Δ T , Δ P ) ,$$

and thus, f-g can be expressed as Formula 3 using a function Z.

$$f - g = Z ( Δ T , Δ P ) \qquad Formula 3$$

Here, since ideally f-g=0, values of T and P at which Z(ΔT, ΔP)=0 may be calculated according to Formula 3.

### Method 2

Method 2 is a method for performing etching parameter control by specifying ∫ΔBdz.

First, ∫ΔBdz is calculated by CD measurement at real time at L1 to L4 based on an optical critical dimension (OCD). At this time, a measurement point in a depth direction may be a stacked film having different film types. In the case of the same film, measurement may be performed by dividing a wafer using an SEM or a TEM. As a matter of course, an SEM and a TEM can be also used for stacked films.

∫ΔBdz can be expressed as Formula 4 using a predetermined function R.

$$\int Δ Bdz = R ( Δ T , Δ P ) \qquad Formula 4$$

Here, since ideally ∫ΔBdz=0, values of T and P at which R(ΔT, ΔP)=0 may be calculated according to Formula 4.

There is no particular limitation on how to derive a function described in the present disclosure, and a function can be inductively calculated from experiments.

Since Method 1 is employed in the first embodiment, it is not necessary to calculate a geometric dimensional difference. Method 2 is employed in a second embodiment to be described later.

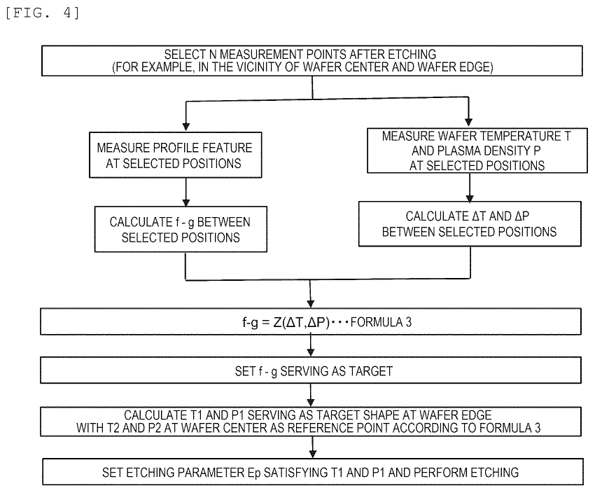

A method for performing etching parameter control according to Method 1 will be described with reference to a flowchart. FIG. 4 is a flowchart showing an example of the method for performing the etching parameter control according to the first embodiment.

First, after wafer etching, N points are selected as measurement points. N is a number larger than 1 for the number of parameters to be calculated. For example, in the present embodiment, there are two points of a wafer center and a wafer edge. In the present embodiment, in order to simplify description, a plasma density is not changed, and a parameter to be calculated is only a temperature, and thus the above two measurement points are sufficient.

Next, a wafer temperature T and a plasma density P at selected positions are measured, and features are also measured.

Next, a wafer temperature difference ΔT and a plasma density difference ΔP between the wafer center and the wafer edge are calculated, and a change amount f-g which is a difference between features is calculated.

Next, referring to Formula 3, in order to calculate a value of the function Z, f-g serving as a target and T2 and P2 at the wafer center serving as a reference point are set. As described above, when P1 at the wafer edge is the same as P2, T1 at the wafer edge is calculated according to Formula 3. This is a temperature at the wafer edge where a target shape is created. Here, a temperature in the vicinity of an edge of an electrostatic chuck is adjusted as an etching parameter Ep that satisfies the T1. In consideration of a heat input balance from plasma, the temperature in the vicinity of the edge of the electrostatic chuck is adjusted such that a temperature at the wafer edge is T1, and then etching is performed.

In this embodiment, an example in which the etching parameter is optimized by using a spatial change amount in a feature is described. Here, although description is given based on a feature calculated based on the secondary electron profile in a CD-SEM serving as secondary electron data, the same flow applies to a feature calculated based on an interference light profile in an OCD serving as interference light data.

### Second Embodiment

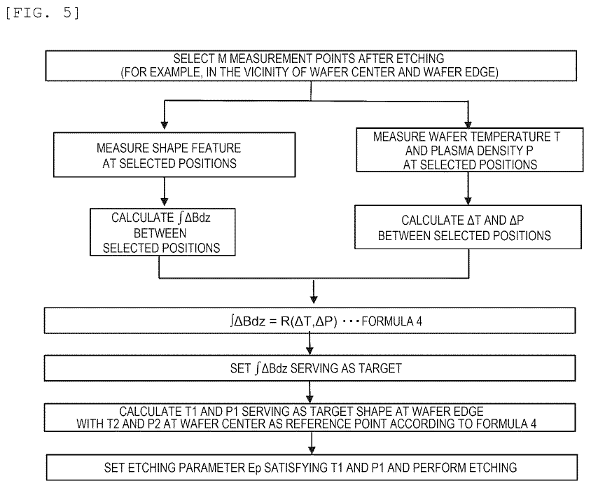

A second embodiment of the invention will be described with reference to FIG. 5. The second embodiment is different from the first embodiment in that Formula 4 is used in Method 2 described above, and since other parts are similar to the first embodiment, the difference will be mainly described. FIG. 5 is a flowchart showing an example of a method for performing etching parameter control according to the second embodiment. In the first embodiment, it is not necessary to calculate a geometric dimensional difference between a target shape and a defective shape, while in the second embodiment, the geometric dimensional difference between the target shape and the defective shape is calculated.

First, after wafer etching, M points are selected as measurement points. M is a number larger than 1 for the number of parameters to be calculated. For example, in the present embodiment, there are two points of a wafer center and a wafer edge. In the present embodiment, in order to simplify description, a plasma density is not changed, and a parameter to be calculated is only a temperature, and thus the above two measurement points are sufficient.

Next, the wafer temperature T and the plasma density P at selected positions are measured, a pattern shape is measured using secondary electron data by a cross-sectional SEM or TEM, or using interference light data by OCD, and a feature related to a geometric dimension is calculated (a feature calculated directly from a geometric dimension of a pattern shape may be referred to as a shape feature).

Next, the wafer temperature difference ΔT and the plasma density difference ΔP at the wafer center and the wafer edge are calculated, and the area difference ∫ΔBdz is calculated. In order to calculate the area difference, there is a method for cutting a wafer by using a cross-sectional SEM or TEM to measure a shape feature related to a dimension of a pattern shape, or a method for calculating a shape feature related to a dimension of a pattern shape by adjusting a light source of an OCD so as to calculate an average pattern width for each film type of L1 to L4 described in FIG. 3. Then, the area difference ∫ΔBdz is calculated by integrating a change amount, which is a geometric dimensional difference (AB) between a shape feature and a target value of a pattern shape, in an etching depth direction.

Next, referring to Formula 4, in order to calculate a value of the function R, ∫ΔBdz serving as a target, and T2 and P2 at the wafer center serving as a reference point are set. As described above, when P1 at the wafer edge is the same as P2, T1 at the wafer edge is calculated according to Formula 4. This is a temperature at the wafer edge where a target shape is created. Here, a temperature in the vicinity of an edge of an electrostatic chuck is adjusted as an etching parameter Ep that satisfies the T1. In consideration of a heat input balance from plasma, the temperature in the vicinity of the edge of the electrostatic chuck is adjusted such that a temperature at the wafer edge is T1, and then etching is performed.

As described above, it is possible to control an etching parameter for detecting and eliminating a defect such as a bowing shape in the etching depth direction, which cannot be obtained by planar dimension data obtained from a top view.

In the present embodiment, a dimension of a pattern shape is directly calculated using secondary electron data or interference light data to specify a shape feature and optimize an etching parameter.

### Third Embodiment

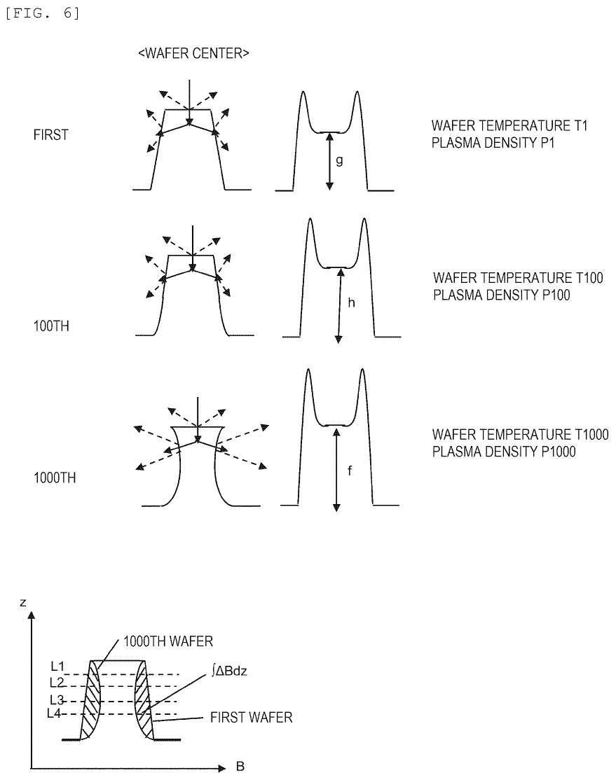

A third embodiment of the invention will be described with reference to FIG. 6. FIG. 6 is a correlation diagram between a pattern shape and a secondary electron profile for a predetermined number of etched wafers. For example, a pattern shape and a feature at a wafer center of each of a first etched wafer, a 100th etched wafer, and a 1000th etched wafer, and a temperature environment and a plasma density environment at each time are shown. Here, for example, the first etched wafer has a target shape, a temperature at a wafer center of the first etched wafer is T1, and a plasma density at the wafer center of the first etched wafer is P1. The 100th etched wafer is defective and has a bowing shape, a temperature at a wafer center of the 100th etched wafer is T100, and a plasma density at the wafer center of the 100th etched wafer is P100. The 1000th etched wafer is defective and has a bowing shape, a temperature at a wafer center of the 1000th etched wafer is T1000, and a plasma density at the wafer center of the 1000th etched wafer is P1000. FIG. 6 shows a graph schematically showing pattern shapes of the first wafer and the 1000th wafer with a vertical axis of z and a horizontal axis of B. L1 to L4 are film type switching lines. A shaded area indicates a shape difference between the first etched wafer and the 1000th etched wafer. An area of a shape difference portion is ∫ΔBdz. Here, a method (Method 1) for optimizing an etching parameter without calculating ∫ΔBdz is used as in the first embodiment.

FIG. 4 is used to describe the above processing in a flow. First, after wafer etching, N points are selected as measurement points. N is a number larger than 1 for the number of parameters to be calculated. For example, in the present embodiment, there are two points of the first wafer and the 1000th wafer. In the present embodiment, in order to simplify description, a plasma density is not changed, and a parameter to be calculated is only a temperature, and thus the above two measurement points are sufficient.

Next, a wafer temperature T and a plasma density P at selected time points are measured, and features are also measured.

Next, a wafer temperature difference ΔT and a plasma density difference ΔP between the first wafer and the 1000th wafer are calculated, and a change amount f-g which is a difference between features is calculated.

Next, referring to Formula 3, in order to calculate a value of the function Z, f-g serving as a target and T1 and P1 of the first wafer serving as a reference point are set. As described above, when P1000 of the 1000th wafer is the same as P1, T1000 of the 1000th wafer is calculated according to Formula 3. This is a temperature of the 1000th wafer in which a target shape is created. Here, a temperature in the vicinity of a center of an electrostatic chuck is adjusted as an etching parameter Ep that satisfies the T1000. In consideration of a heat input balance from plasma, the temperature in the vicinity of the center of the electrostatic chuck is adjusted such that a temperature at the wafer center is T1000, and then etching is performed.

In the present embodiment, an example in which an etching parameter is optimized by using a temporal change amount in a feature is described. Here, although description is given based on a feature calculated based on the secondary electron profile in a CD-SEM, the same flow applies to a feature calculated based on an interference light profile in an OCD.

### Fourth Embodiment

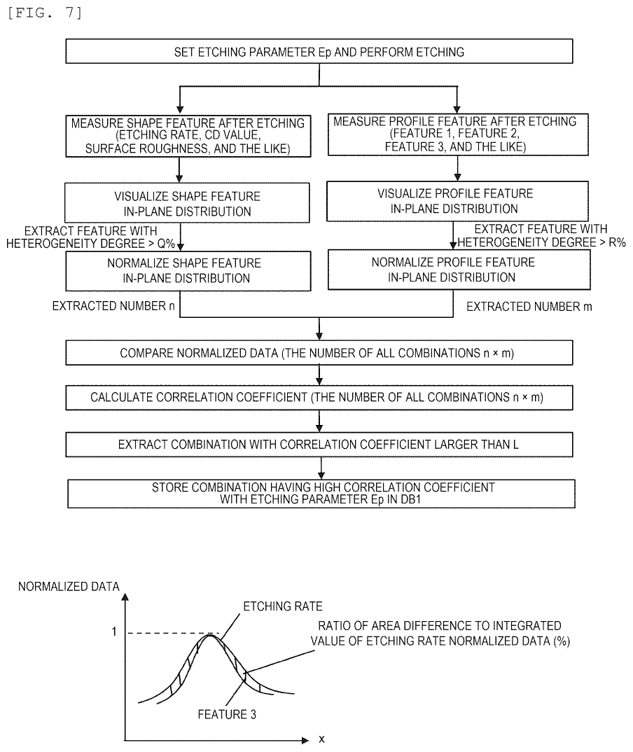

A fourth embodiment of the invention will be described with reference to FIG. 7. FIG. 7 is a flowchart showing an example of a method for extracting a combination of features having a high correlation coefficient with an etching parameter.

First, an etching parameter Ep is set and an etching processing is performed.

Next, a shape feature is measured after the etching. As the shape feature, various features such as an etching rate, a CD value, and surface roughness are considered. A measurement point is more than 1.

After the etching, a profile feature is measured. As the feature, not only an intensity of a secondary electron amount at a center of a top surface of a pattern obtained based on the secondary electron profile described above, but also various features (a feature 1, a feature 2, a feature 3, and the like) can be considered. A measurement point is more than 1.

Next, a feature in-plane distribution is visualized and a heterogeneity degree is calculated. Accordingly, for example, the heterogeneity degree is calculated according to (maximum value-average value)/average value×100(%) using a maximum value of a variation from average data of data related to a measured feature. Then, a feature in which the heterogeneity degree exceeds a predetermined ratio (%) is extracted (for example, the number of extracted shape features when the predetermined heterogeneity degree is set to Q % is defined as n, and the number of extracted profile features when the predetermined heterogeneity degree is set to R % is defined as m).

The in-plane distribution is normalized for each extracted feature. Here, for example, a maximum value for each feature is normalized to 1.

Next, normalized data of a shape feature in-plane distribution and normalized data of a profile feature in-plane distribution are compared to calculate a correlation coefficient. As an example of calculating the correlation coefficient, FIG. 7 shows a relationship between normalized data and a measurement position (x) on a wafer. Here, for example, in the case of an etching rate and the feature 3, an area of a portion having a difference (an area difference) is calculated by superimposing normalized data. As an example of a formula for calculating a correlation coefficient based on a ratio of an area difference to an integrated value of etching rate normalized data, there is a formula of 100−ratio (%) of area difference to integrated value of etching rate normalized data=correlation coefficient. This is calculated using the number of all combinations n×m, and a combination with a correlation coefficient larger than L (%) is extracted and stored in a database (DB1) in a server.

In this manner, it is possible to accumulate correlation data related to a feature having a high correlation with the etching parameter Ep in the DB1. Accordingly, it is possible to search for an etching parameter having a high correlation based on a predetermined feature from the DB1 by a method such as machine learning and control the etching parameter to make an in-plane distribution uniform.

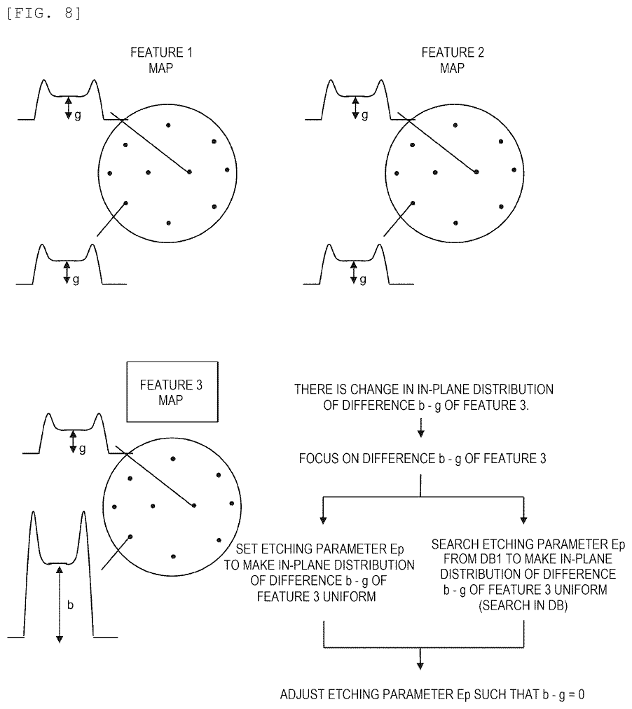

An example of actual use will be described. FIG. 8 is a schematic diagram showing a feature map according to the fourth embodiment. Although maps of the features 1 to 3 serving as features are shown, attention is focused on the feature 3 in which there is a difference in a feature in-plane distribution (a heterogeneity degree is high). Since an etching parameter having a high correlation with the feature 3 is stored in the DB1, and the etching parameter is accurately adjusted to make the feature 3 uniform by searching (search in the DB). It is also possible to extract an optimum etching parameter from past experimental data and perform manual setting.

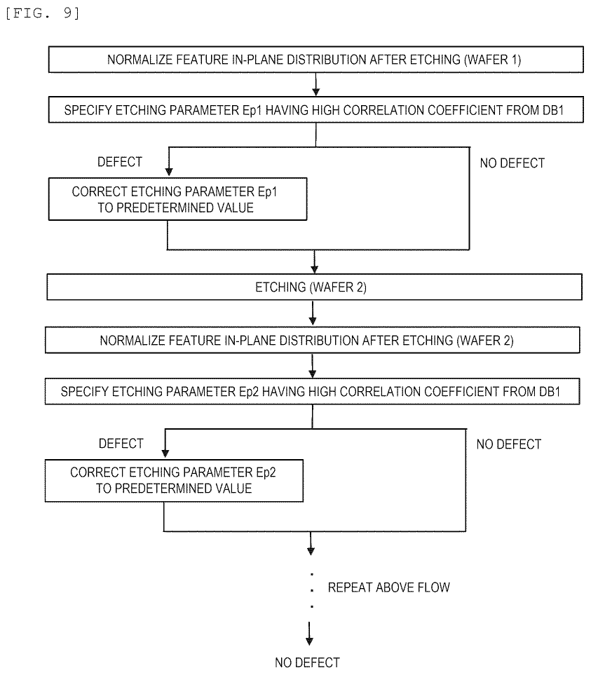

The above-described operation will be described with a flowchart. FIG. 9 is a flowchart showing an example of a method for performing etching parameter control according to the fourth embodiment.

First, a feature in-plane distribution after etching is normalized for a wafer 1. That is, a maximum value of a feature is set to 1.

Next, an etching parameter Ep1 having a high correlation coefficient is specified from the above-described DB1 by using the feature in-plane distribution. Machine learning can also be used for the specification. When there is a significant spatial or temporal difference (change amount) in a feature and that is a defect, the etching parameter Ep1 is corrected to a predetermined value, and etching processing is performed again on a wafer 2. Thereafter, the same processing is repeated until there is no problem in a feature, and a desired etching processing recipe can be obtained. Accordingly, a target shape can be formed by accurately controlling an etching parameter for a feature having a problem of a heterogeneous in-plane distribution.

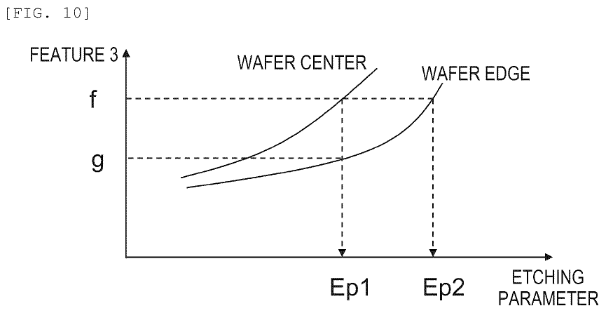

FIG. 10 shows a method for further efficiently calculating an etching parameter. FIG. 10 is a correlation diagram between a feature and an etching parameter. An example of a correlation diagram between an etching parameter and the feature 3 (for example, an intensity of a secondary electron amount at a center of a top surface of a pattern) at a wafer center and a wafer edge is shown. In etching, gas pressure in an outer peripheral portion of a wafer is low, and an adhesion rate of a reaction product is often smaller in the outer peripheral portion than that in a center portion. Therefore, a thickness of the reaction product attached to a pattern side wall may be different between the center portion and the outer peripheral portion of the wafer. It is considered that there is a difference in a feature due to a difference in a shape and roughness of a side wall. In other words, even with the same shape, since a material and surface roughness inside a pattern side wall differ, an amount of secondary electrons emitted from the side wall also differs between a center portion and an outer periphery of a wafer. In FIG. 10 as well, when the feature 3 is f, etching parameters at a wafer center and a wafer edge are Ep1 and Ep2 and are different. When the etching parameter remains at Ep1, since a feature difference f-g will occurs, a defect will occur. As approaching to the center from the wafer edge, the etching parameter Ep1 of the wafer edge may be changed to Ep2.

Although embodiments of the invention have been described above, the invention is not limited to the embodiments described above, and various changes can be made without departing from the gist of the invention.

For example, in the embodiments, a flow is described in which etching parameter control is performed and a difference between features is eliminated by visualizing and normalizing a feature distribution on a wafer and calculating a correlation coefficient. The visualization method, the normalization method, and the correlation coefficient calculation method described here are examples.

Although the server is described as a component that performs the etching parameter control in the embodiments described above, a virtual area, a PC terminal, and a mobile terminal may be used instead of the server, and the same effects can be obtained not only by a communication method of SMB communication, but also by FTP communication, NFS communication, and the like.

Although an etching described as an example of a semiconductor manufacturing apparatus in the embodiments described above, the same effects can be obtained by other manufacturing apparatuses such as a plasma CVD apparatus, an ashing apparatus, a surface modification apparatus, and the like.

Although a CD-SEM is described as an example of a semiconductor inspection apparatus in the embodiments described above, the same effects can be obtained by other inspection apparatus such as an OCD, a TEM, and an XRR.

Aspects that may be contents of the invention will be described below, but are not limited thereto.

### Aspect 1

A server, in which
an etching parameter of a semiconductor manufacturing apparatus is controlled to obtain a desired processing result of the semiconductor manufacturing apparatus based on correlation data between the etching parameter and a change amount between a target value and a feature of an etched shape formed on a sample, and
the feature is a value obtained based on secondary electron data from a surface of the sample or interference light data from the surface of the sample.

### Aspect 2

The server according to aspect 1, in which
the feature is a value obtained from a dimension of the etched shape of the sample based on the secondary electron data or the interference light data.

### Aspect 3

The server according to aspect 1 or 2, in which
the change amount is a value of a spatial or temporal change.

### Aspect 4

The server according to any one of aspects 1 to 3, in which
the correlation data includes a value obtained from an integrated value in an etching depth direction of the change amount related to a dimensional difference between the etched shape and the target shape.

### Aspect 5

The server according to aspect 4, in which
the correlation data includes a difference between an etching parameter related to the etched shape and an etching parameter related to the target shape, and the integrated value.

### Aspect 6

The server according to aspect 1, in which
when the feature is obtained based on the secondary electron data, the feature is adjusted by an acceleration voltage of an electron gun of a CD-SEM.

### Aspect 7

The server according to any one of aspects 1 to 6, in which
the sample has a plurality of films formed thereon.

### Aspect 8

The server according to aspect 3, in which
when the change amount is a value of a spatial change, the change amount is a value of a change in a radial direction of the sample or in a circumferential direction of the sample.

### Aspect 9

The server according to any one of aspects 1 to 8, in which
the correlation data includes a correlation coefficient for a predetermined etching parameter calculated by visualizing and normalizing an in-plane distribution of the sample for a plurality of features.

### Aspect 10

The server according to aspect 9 including:
a database configured to store data related to a combination of an etching parameter and a feature having the high correlation coefficient.

### Aspect 11

The server according to aspect 10, in which
the combination of the etching parameter and the feature having the high correlation coefficient is specified from the database, and when the feature is different from the target value, the etching parameter is corrected.

### Aspect 12

The server according to aspect 11, in which
the etching parameter is controlled by controlling a temperature of the sample.

### Aspect 13

A semiconductor device manufacturing system including:
the server according to any one of aspects 1 to 12.

### Aspect 14

A semiconductor device manufacturing method including:
a step of obtaining a feature based on secondary electron data from a surface of a sample or interference light data from the surface of the sample;
a step of obtaining correlation data between an etching parameter of a semiconductor manufacturing apparatus and a change amount between a target value and a feature of an etched shape formed on the sample; and
a step of controlling the etching parameter to obtain a desired processing result of the semiconductor manufacturing apparatus based on the correlation data.

### REFERENCE SIGNS LIST

10: semiconductor device manufacturing system
101: CD-SEM PC
102: semiconductor manufacturing apparatus PC
103: server
104: semiconductor inspection apparatus
105: semiconductor manufacturing apparatus

1. A server, wherein
an etching parameter of a semiconductor manufacturing apparatus is controlled to obtain a desired processing result of the semiconductor manufacturing apparatus based on correlation data between the etching parameter and a change amount between a target value and a feature of an etched shape formed on a sample, and
the feature is a value obtained based on secondary electron data from a surface of the sample or interference light data from the surface of the sample.

2. The server according to claim 1, wherein
the feature is a value obtained from a dimension of the etched shape of the sample based on the secondary electron data or the interference light data.

3. The server according to claim 1, wherein
the change amount is a value of a spatial or temporal change.

4. The server according to claim 2, wherein
the correlation data includes a value obtained from an integrated value in an etching depth direction of the change amount related to a dimensional difference between the etched shape and the target shape.

5. The server according to claim 4, wherein
the correlation data includes a difference between an etching parameter related to the etched shape and an etching parameter related to the target shape, and the integrated value.

6. The server according to claim 1, wherein
when the feature is obtained based on the secondary electron data, the feature is adjusted by an acceleration voltage of an electron gun of a CD-SEM.

7. The server according to claim 1, wherein
the sample has a plurality of films formed thereon.

8. The server according to claim 3, wherein
when the change amount is a value of a spatial change, the change amount is a value of a change in a radial direction of the sample or in a circumferential direction of the sample.

9. The server according to claim 1, wherein
the correlation data includes a correlation coefficient for a predetermined etching parameter calculated by visualizing and normalizing an in-plane distribution of the sample for a plurality of features.

10. The server according to claim 9 comprising:
a database configured to store data related to a combination of an etching parameter and a feature having the high correlation coefficient.

11. The server according to claim 10, wherein
the combination of the etching parameter and the feature having the high correlation coefficient is specified from the database, and when the feature is different from the target value, the etching parameter is corrected.

12. The server according to claim 11, wherein
the etching parameter is controlled by controlling a temperature of the sample.

13. A semiconductor device manufacturing system comprising:
a server configured to control an etching parameter of a semiconductor manufacturing apparatus to obtain a desired processing result of the semiconductor manufacturing apparatus based on correlation data between the etching parameter and a change amount between a target value and a feature of an etched shape formed on a sample,
wherein the feature is a value obtained based on secondary electron data from a surface of the sample or interference light data from the surface of the sample.

14. A semiconductor device manufacturing method comprising:
a step of obtaining a feature based on secondary electron data from a surface of a sample or interference light data from the surface of the sample;
a step of obtaining correlation data between an etching parameter of a semiconductor manufacturing apparatus and a change amount between a target value and a feature of an etched shape formed on the sample; and
a step of controlling the etching parameter to obtain a desired processing result of the semiconductor manufacturing apparatus based on the correlation data.
